(19) United States
(12) Patent Application Publication
(10) Pub. No.: US 2026/0012011 A1
(43) Pub. Date: Jan. 8, 2026

(54) VOLTAGE PROTECTION CIRCUIT FOR HALF-BRIDGE FET DRIVER

(71) Applicant: Texas Instruments Incorporated, Dallas, TX (US)

(72) Inventors: Satish Vemuri, Raleigh, NC (US); Yang Xiao, Dallas, TX (US); Piranave Kaliannagounder Arumugan, Bangalore (IN); Vipul Singhal, Bangalore (IN); Amal Kumar Kundu, Bangalore (IN)

(21) Appl. No.: 19/091,484

(22) Filed: Mar. 26, 2025

Related U.S. Application Data
(60) Provisional application No. 63/668,460, filed on Jul. 8, 2024.

(51) Int. Cl. H02H 9/04; H01L 23/60; H02M 1/32; H10D 89/60

(52) U.S. Cl. CPC H02H 9/046; H01L 23/60; H02M 1/32; H10D 89/911; H10D 89/921

(57) ABSTRACT

In one example, a circuit includes a first transistor having a first terminal coupled to a first supply voltage source, a second transistor coupled between a second terminal of the first transistor and a ground terminal, and a voltage clamp circuit coupled between the first supply voltage source and the ground terminal. The circuit may further include a first switch coupled between a control terminal of the first transistor and a second supply voltage source, the first switch having a control terminal coupled to the second terminal of the first transistor, a second switch coupled between a control terminal of the second transistor and the second supply voltage source, the second switch having a control terminal coupled to the ground terminal, and a filter coupled between the control terminal of the second transistor and the ground terminal.

### TECHNICAL FIELD

This description relates to power converters and to techniques for protecting power converter circuitry from over-voltage surges due to electrostatic discharge.

### BACKGROUND

Monolithic half-bridge drivers for switching power converters may utilize electrostatic discharge (ESD) protection circuitry to prevent or reduce damage in the event of ESD-induced voltage spikes on one or more power rails of the driver circuit. In some cases, high-voltage Human Body Model (HBM) clamp circuits are used to clamp the voltage between a power rail and a ground terminal to below an acceptable limit. To effectively protect power transistors in the driver circuit, the HBM clamp circuit should limit the voltage to a level that is less than the breakdown voltage of the power transistors. However, the HBM clamp circuit generally also includes a high-voltage transistor and there are limited combinations of high-voltage transistors available for use in the HBM clamp circuit and in the driver circuit being protected. As a result, design trade-offs tend to limit the operating voltage range of the driver circuit, and non-trivial issues remain with respect to achieving drivers that can be adequately protected from ESD events.

### SUMMARY

According to one example, a circuit comprises: a first transistor having a first terminal coupled to a first supply voltage source; a second transistor coupled between a second terminal of the first transistor and a ground terminal; and a voltage clamp circuit coupled between the first supply voltage source and the ground terminal. The circuit further comprises: a first switch coupled between a control terminal of the first transistor and a second supply voltage source, the first switch having a control terminal coupled to the second terminal of the first transistor; a second switch coupled between a control terminal of the second transistor and the second supply voltage source, the second switch having a control terminal coupled to the ground terminal; and a filter coupled between the control terminal of the second transistor and the ground terminal.

According to another example, a circuit comprises: at least one driver coupled between first and second supply voltage terminals; control circuitry coupled to the at least one driver, the control circuitry comprising at least one transistor; an electrostatic discharge (ESD) clamp circuit coupled between the first supply voltage terminal and a ground terminal, the ESD clamp circuit having a clamp voltage that is higher than a breakdown voltage of the transistor; and protection circuitry coupled to the transistor and configured to extend a voltage rating of the transistor in combination with the protection circuitry to at least the clamp voltage of the ESD clamp circuit.

According to another example, a power converter comprises: a high-side switching element coupled between an input voltage terminal and a switching terminal; a low-side switching element coupled between the switching terminal and a ground terminal; and a half-bridge driver circuit. The half-bridge driver circuit comprises: a first driver coupled between first and second floating supply voltage terminals and to a control terminal of the high-side switching element; a second driver coupled between a low-voltage supply source and the ground terminal and to a control terminal of the low-side switching element; control circuitry coupled to at least one of the first driver or the second driver, the control circuitry comprising at least one laterally-diffused metal oxide semiconductor (LDMOS) transistor; an electrostatic discharge (ESD) clamp circuit coupled between the first floating supply voltage terminal and the ground terminal, the ESD clamp circuit having a clamp voltage that is higher than a breakdown voltage of the LDMOS transistor; and protection circuitry coupled to the LDMOS transistor and configured to extend an ESD voltage capability of a combination of the LDMOS transistor and the protection circuitry to above the clamp voltage of the ESD clamp circuit.

### BRIEF DESCRIPTION OF THE DRAWINGS

FIG. 1 is a block diagram of a switching power converter including a half-bridge driver with voltage surge protection circuitry, according to certain examples.

FIG. 2 is a schematic diagram of showing driver circuitry of the power converter of FIG. 1, in an example.

FIG. 3 is a schematic diagram of one implementation of the voltage protection circuitry that may be included in the driver circuitry, in an example.

FIG. 4 is a schematic diagram of an implementation of the voltage protection circuitry that may be included in the driver circuitry, in another example.

### DETAILED DESCRIPTION

Techniques are described for electrostatic discharge (ESD) protection of driver circuitry for power converter applications. The techniques described herein may be used in a variety of circuits and systems, including DC-DC switching power converters, for example. In certain examples, the techniques can be applied in a half-bridge field effect transistor (FET) driver circuit that may be part of, or otherwise installed into, a power converter or other device. As described in more detail below, control circuitry that can be coupled to a switching element driver, for example, may include at least one transistor that is to be protected, an ESD clamp circuit having a clamp voltage that is higher than a breakdown voltage of the transistor, and protection circuitry coupled to the transistor and configured to extend an ESD voltage capability of a combination of the transistor and the protection circuitry to at least the clamp voltage of the ESD clamp circuit. In one such example, a driver circuit comprises a first transistor having a first terminal coupled to a first supply voltage source, a second transistor coupled between a second terminal of the first transistor and a ground terminal, and a voltage clamp circuit coupled between the first supply voltage source and the ground terminal. The driver circuit may further comprise a first switch and a second switch. The first switch is coupled between a control terminal of the first transistor and a second supply voltage source. The first switch may have a control terminal coupled to the second terminal of the first transistor. The second switch is coupled between a control terminal of the second transistor and the second supply voltage source, the second switch having a control terminal coupled to the ground terminal. The circuit may further include a filter coupled between the control terminal of the second transistor and the ground terminal. These and other aspects are described in more detail below.

### General Overview

Power converter driver circuits are used in a wide variety of devices and applications, including in DC-DC power converters. These driver circuits include components configured and arranged to provide various different functionality within the driver circuitry and may typically include one or more transistors with a relatively high voltage rating. For example, one or more laterally diffused metal-oxide semiconductor (LDMOS) transistors with a high voltage rating (e.g., 150 volts (V), 170V, 200V, etc.) can be used to provide functionality such as zero-crossing detection (ZCD) and reporting (also referred to as zero-voltage detection (ZVD) and/or reporting), level shifting, and/or regulated boot switching, to name a few examples. An LDMOS transistor is a planar double-diffused MOS field effect transistor (MOSFET) useful in a variety of high-voltage circuitry and applications. It can be advantageous to protect these high-voltage transistors from ESD-induced voltage spikes that could damage the transistors and other components of the driver circuit. Accordingly, as described above, an HBM clamp circuit can be used to limit the voltage between the supply rails for the transistor(s) during an ESD event to an acceptable voltage level so that the drain-source voltage (Vds) of the transistor does not exceed its breakdown voltage capability. However, due to limited available combinations of high-voltage LDMOS transistors for the driver circuitry and the HBM clamp circuit, there is a trade-off between the available operating voltage range and the ESD rating for these devices. For instance, one possible approach involves constructing a FET driver circuit such that the clamp voltage set by the HBM clamp circuit is less than the breakdown voltage of the LDMOS device, but greater than the operating voltage of the LDMOS device. As a result, the operating voltage range of the LDMOS device is decided by the ESD voltage rating. Thus, a higher voltage-rated LDMOS is used in combination with an HBM clamp circuit that sets a lower clamp voltage (such that the breakdown voltage of the LDMOS device is higher than the clamp voltage, and the device survives an ESD strike). However, this results in the normal operating voltage of the circuit in which the LDMOS is used being de-rated (or reduced) relative to the capability of the LDMOS device. For example, although an LDMOS device may have a 200V voltage rating, the operating voltage may be restricted to no more than ˜170V in order to achieve satisfactory ESD protection using an HBM clamp circuit. Thus, the full potential operating voltage range of high-voltage transistors may not be accessible, limiting the ability to support high-voltage applications.

Accordingly, techniques are described herein by which the operating voltage range of a driver circuit can be extended while maintaining the same ESD protection rating/capability. In some examples, the techniques described herein can be applied in a half-bridge FET driver circuit, as described further below, although other driver circuits may also benefit from use of the techniques described herein. According to certain examples, a cascode transistor device is used in combination with a transistor (e.g., an LDMOS transistor) being protected to extend the effective breakdown voltage of the transistor. With this arrangement, a higher HBM clamp voltage (e.g., higher than the breakdown voltage of the transistor alone) can be shared across the combination of the transistor and the cascode device. As this allows the clamp voltage to be increased, the operating voltage range of the transistor also can be increased, thereby allowing the circuitry in which the transistor is used to employ up to the full rated voltage of the transistor. The cascode device may be configured to create a separate voltage domain in the case of an ESD event, thereby isolating the transistor from potentially damaging high voltage spikes, as described in more detail below. In one example, inputs and outputs of this “ESD domain” are isolated using high voltage switches.

In one example, a circuit included in, or useable in conjunction with, a driver circuit comprises a first transistor having a first terminal coupled to a first supply voltage source, and a second transistor coupled between a second terminal of the first transistor and a ground terminal. In some such examples, the first and second transistors are LDMOS devices that are coupled in a cascode configuration, although other transistor technologies may be used. The circuit may include a voltage clamp circuit that is coupled between the first supply voltage source and the ground terminal. The circuit further includes a first switch and a second switch. The first switch is coupled between a control terminal of the first transistor and a second supply voltage source, and has a control terminal coupled to the second terminal of the first transistor. The second switch is coupled between a control terminal of the second transistor and the second supply voltage source, and has a control terminal coupled to the ground terminal. These switches can be used to isolate the gates of the first and second transistors if an ESD event occurs, as described further below. In some examples, the circuit further includes a filter coupled between the control terminal of the second transistor and the ground terminal.

### Example Circuitry

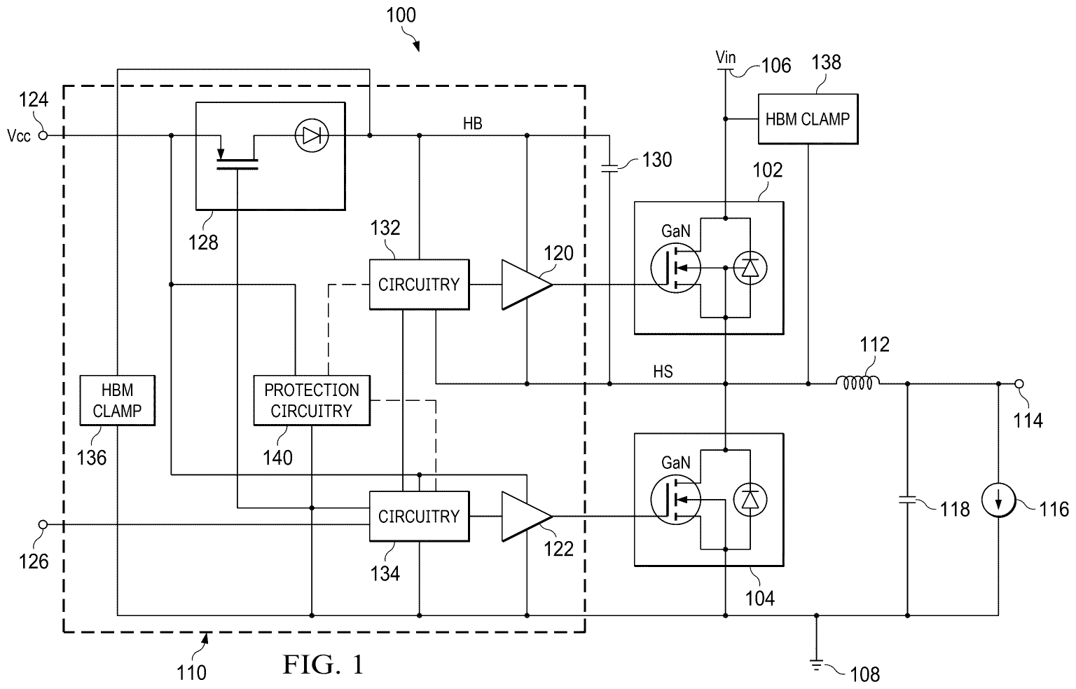

FIG. 1 is a diagram illustrating an example of a switching power converter 100 including over-voltage protection circuitry, according to certain aspects. In the illustrated example, the switching power converter 100 includes a high-side transistor 102 and a low-side transistor 104, which may also be called switching elements. The high-side transistor 102 is coupled between an input voltage terminal 106 and a first supply voltage source, HS, (also referred to as a supply voltage rail, supply voltage terminal, or switching terminal). The low-side transistor 104 is coupled between the first supply voltage terminal, HS, and a ground terminal 108. A driver circuit 110 is used to drive the high-side and low-side transistors 102, 104. In some examples, the driver circuit 110 is a half-bridge FET driver circuit; however, in other examples, a different configuration for the driver circuit 110 can be used.

In some examples, an inductor 112 is coupled between the first supply voltage terminal, HS, and an output terminal 114, to which an external load 116 may be coupled. The load 116 may be coupled between the output terminal 112 and the ground terminal 108, as shown. The power converter 100 may receive an input voltage, Vin, at the input voltage terminal 106 and a provide a regulated output voltage (e.g., Vout) at the output terminal 114. In some examples, a load capacitor 118 can be coupled in parallel with the load between the output terminal 114 and the ground terminal 108.

Continuing with the example of FIG. 1, the driver circuit 110 may include a high-side gate driver 120 coupled to a control terminal of the high-side transistor 102 and configured to drive the high-side transistor 102. The driver circuit 110 may similarly include a low-side gate driver 122 coupled to a control terminal of the low-side transistor 104 and configured to drive the low-side transistor 104. In some examples, the high-side transistor 102 is an N-channel, three terminal enhancement-mode MOSFET having a drain terminal coupled to the input voltage terminal 106 and a source terminal coupled to the switching terminal, HS. Similarly, in the example of FIG. 1, the low-side transistor 104 is an N-channel, three terminal enhancement-mode MOSFET having a drain terminal coupled to the switching terminal, HS, and a source terminal coupled to the ground terminal 108. However, in other examples, other types and/or configurations of the high-side and/or low-side transistors 102, 104 can be used. For instance, in some other examples, the high-side and low-side transistors 102, 104 are implemented as gallium nitride (GaN) transistors or bipolar junction transistors (BJTs). More generally, the high-side and low-side transistors 102, 104 may be implemented with any suitable transistor technologies and/or semiconductor materials.

According to certain examples, the driver circuit 110 includes a voltage terminal 124 that receives an operating voltage, Vcc, and therefore may be described as a Vcc terminal. In some examples, the operating voltage, Vcc, is a relatively low voltage, such as ˜5V, for example. The driver circuit 110 may further include one or more input/output (I/O) terminals 126 that allow the driver circuit 110 to receive input data/controls from external circuitry and/or to provide output data to external circuitry, as described further below. In some examples, including some examples in which the high-side transistor 102 is an N-channel MOSFET, the high-side gate driver 120 may be implemented using a bootstrap gate driver to provide a gate voltage greater than the supply voltage so to fully turn on the high-side transistor 102. Accordingly, the driver circuit 110 may include a boot diode 128 coupled between the Vcc terminal 124 and a supply terminal of the high-side gate driver 120. The supply terminal of the high-side gate driver 120 is coupled to a second supply voltage source, HB, (also referred to as a supply voltage rail or supply voltage terminal). A boot capacitor 130 may be coupled across the high-side gate driver 120 between the second supply voltage terminal, HB, and the first supply voltage terminal, HS, as shown in FIG. 1.

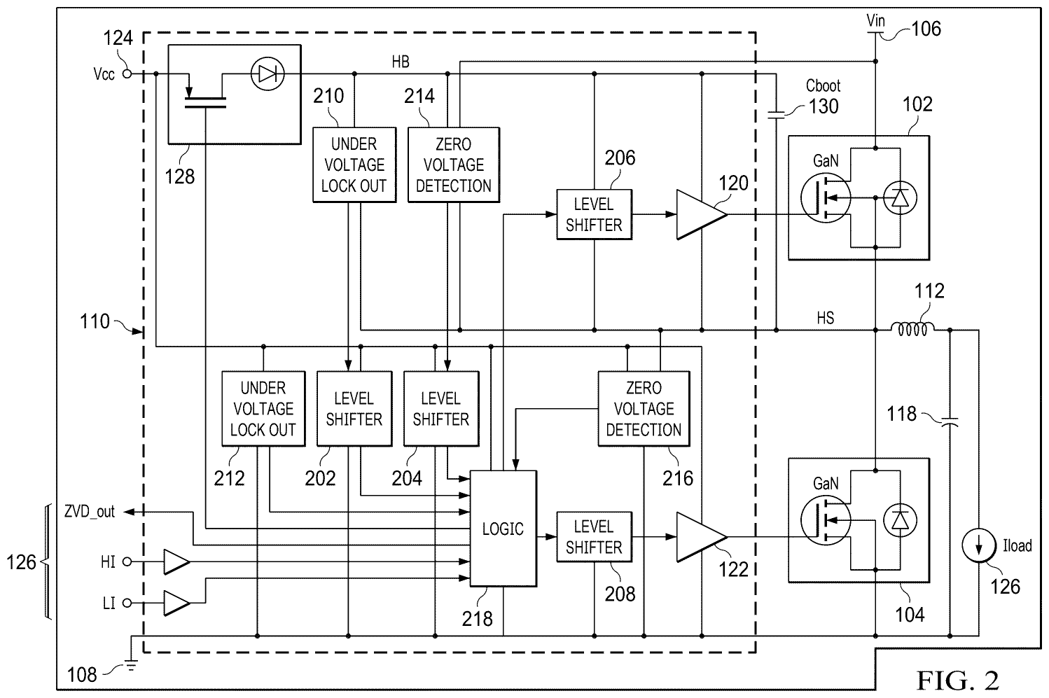

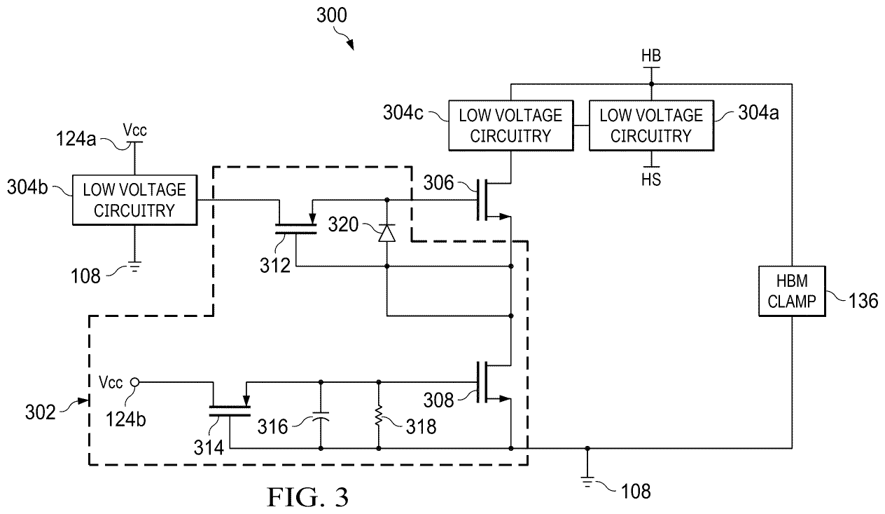

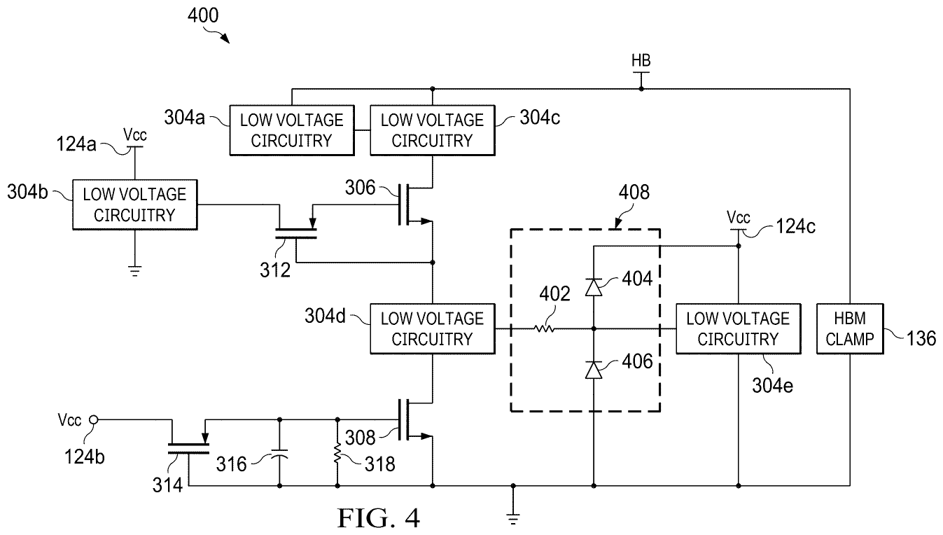

The driver circuit 110 may include circuitry 132 coupled to the high-side gate driver 120, and circuitry 134 coupled to the low-side gate driver 122. In some examples, one or more components of the circuitry 132 is/are coupled to one or more components of the circuitry 134. The circuitry 132, 134 is configured to provide any one or more of various functions that may be associated with the driver circuit 110 (such as zero-crossing detection/reporting, level shifting, etc.), examples of which are described further with reference to FIG. 2. The circuitry 132, 134 may include one or more high-voltage transistors, such as 200V LDMOS transistors, for example, to support at least some of the functionality associated with the circuitry 132, 134. To protect the circuitry 132, 134 from ESD events, the power converter 100 may include a first HBM clamp circuit 136 coupled between the second supply voltage terminal, HB, and the ground terminal 108, and a second HBM clamp circuit 138 coupled between the input voltage terminal 106 and the first supply voltage terminal, HS. The HBM clamp circuits 136, 138 may be part of, or external to, the driver circuit 110. However, as described above, using the HBM clamp circuits 136, 138 alone, for a given ESD rating, it may not be possible to configure the driver circuit 110 to take advantage of the full operating voltage range of the high-voltage transistor(s) used in the circuitry 132 and/or 134. Accordingly, the driver circuit 110 may include protection circuitry 140 that is configured to extend or enhance the effective breakdown voltage of the high-voltage transistor(s) used in the circuitry 132 and/or 134, such that the operating voltage range of the transistor(s) can be increased, while maintaining the same ESD rating provided via the HBM clamp circuits 136 and/or 138. Examples of the protection circuitry 140, and operation thereof, are described further below with reference to FIGS. 3 and 4.

Turning to FIG. 2, there is illustrated an example of the power converter 100 of FIG. 1. In this example, the driver circuit 110 is implemented as a monolithic half-bridge driver that provides zero-voltage detection, level shifting, and/or regulated boot switching, in addition to providing drive signals for the high-side and low-side transistors 102, 104. In some examples, the driver circuit 110 is implemented on a single die; however, in other examples, the functionality of the driver circuit 110 may be spread across multiple die. The driver circuit 110 may be implemented on the same die, or a different die, as the high-side and low-side transistors 102, 104.

According to certain examples, the driver circuit 110 operates in two voltage domains: a low-voltage domain and a high-voltage domain. A controller portion (or controller functionality) of the driver circuit 110 operates in the low-voltage domain (e.g., ˜5V, 3.2 V, etc.) that is defined between the Vcc terminal 124 and the ground terminal 108. The first and second supply voltage terminals, HB and HS, define a floating supply domain, referred to as the high-voltage domain. The boot capacitor 130 coupled between the supply voltage terminals, HB and HS, acts as a floating power supply. In some examples, the difference between the voltages at the second supply voltage terminal, HB, and the first supply voltage terminal, HS, is regulated to a set level, such as 5V, for example, for efficient and robust operation of the high-side transistor 102. As described above, an input voltage, Vin, may be received via the input voltage terminal 106. In some examples, the input voltage, Vin, is a relatively high voltage, such as 200V, for example. The first supply voltage terminal, HS, switches between the voltage levels at the ground terminal 108 and the input voltage terminal 106. Accordingly, the driver circuit 110 may include level shifters 202, 204, 206, and 208 that allow for transfer of signals across the two voltage domains. One or more of these level shifters 202, 204, 206, 208 may include a high-voltage LDMOS transistor, for example. In some examples, the level shifter 206 is part of the circuitry 132 of FIG. 1, and the level shifters 202, 204, 208 are part of the circuitry 134 of FIG. 1. However, other configurations may be implemented.

Continuing with the example of FIG. 2, the driver circuit 110 may include a high-side under-voltage lock-out (UVLO) circuit 210 and/or a low-side UVLO circuit 212. In some examples, the high-side UVLO circuit 210 is part of the circuitry 132 of FIG. 1 and the low-side UVLO circuit 212 is part of the circuitry 134 of FIG. 1. The UVLO circuits 210, 212 may be used to turn off power to some or all of the components of the driver circuit 110, thereby preventing unpredictable and/or potentially damaging operation of the power converter 100, under certain conditions. For example, the high-side UVLO circuit 210 may be used to turn off power to certain components when the boot voltage across the boot capacitor 130 is too low (e.g., when the difference between the voltage at the second supply voltage terminal, HB, and the voltage at the first supply voltage terminal, HS, is insufficient for the high-side circuitry to work properly).

As described above, in some examples, the driver circuit 110 is configured to provide zero-voltage detection and reporting functionality. Zero-voltage detection may be performed for the high-side circuitry and/or the low-side circuitry. Accordingly, in the example of FIG. 2, the driver circuit 110 includes a high-side ZVD circuit 214 and a low-side ZVD circuit 216. In addition, the I/O terminal(s) 126 may include a ZVD_out terminal to provide ZVD reporting to external circuitry or devices. In some examples, the high-side ZVD circuit 214 is part of the circuitry 132 of FIG. 1 and the low-side ZVD circuit 216 is part of the circuitry 134 of FIG. 1. The ZVD circuits 214, 216 may include one or more high-voltage LDMOS transistors that act as switches to block the high-voltage signals present on the first and/or second supply voltage terminals, HS and HB.

Continuing with the example of FIG. 2, the driver circuit 110 may further include logic circuitry 218 that provides driver control signals to the high-side gate driver 120 and the low-side gate driver 122. In some examples, the driver control signals are pulse-width modulation signals. The I/O terminals 126 may include one or more control terminals to receive control signals for the high-side (HI) and low-side (LI) that the logic circuitry 218 converts into the driver control signals for the high-side and low-side gate drivers 120, 122. The logic circuitry 218 may be part of the circuitry 134 of FIG. 1, and may be part of the controller functionality described above that operates in the low-voltage domain.

Thus, FIG. 2 illustrates one example of a multi-functional, monolithic half-bridge driver that includes both high-voltage and low-voltage circuitry, and which may use one or more high-voltage LDMOS transistors within the circuitry to implement various functionality, as described above. However, it will be appreciated that the driver circuit 110 of FIG. 1 may be implemented in other ways and may include (or omit) functionality different than that described with respect to FIG. 2. Techniques and circuitry used to implement the protection circuitry 140 of FIG. 1 may thus be applied to numerous examples and configurations of driver circuits 110, including numerous variations of the example shown in FIG. 2.

Referring to FIG. 3, there is illustrated a circuit 300 that includes protection circuitry 302, according to one example. The protection circuitry 302 may be an example of, or a portion of an example of, the protection circuitry 140 of FIG. 1. Thus, the circuit 300 may represent a portion of the driver circuit 110 of FIG. 1 and/or FIG. 2, for example. The circuit 300 includes low-voltage circuitry 304. The low-voltage circuitry 304 may be part of the circuitry 132 and/or 134 of FIG. 1. In the example of FIG. 3, a first portion of low-voltage circuitry 304a is coupled between the first and second supply voltage terminals, HS and HB, and a second portion of the low-voltage circuitry 304b is coupled between a Vcc terminal 124a and the ground terminal 108. A third portion of the low-voltage circuitry 304c is coupled to the second supply voltage terminal, HB. The low-voltage circuitry 304 may include numerous components in numerous different configurations, depending on the construction and functionality of the driver circuit 110, as will be appreciated in light of this disclosure.

The circuit 300 includes a first transistor 306 that is coupled to the low-voltage circuitry portions 306b and 304c. This first transistor 306 may be a high-voltage transistor, such as a high-voltage (e.g., 200V) LDMOS transistor, for example. The first transistor 306 may be part of the circuitry 132 or 134 described above. In some implementations, the driver circuit 110 may include multiple high-voltage transistors that are part of the various circuitry implementing different functions, some examples of which are described above. Accordingly, while one first transistor 306 and one example of the protection circuitry 302 are illustrated in FIG. 3, it will be appreciated that the driver circuit 110 may include multiple first transistors 306 and multiple copies of the protection circuitry 302. In addition, while the protection circuitry 302 is shown and described with reference to the HBM clamp circuit 136 coupled between the second supply voltage terminal, HB, and the ground terminal 108, it will be appreciated that the same techniques described herein may be applied to operate in conjunction with the HBM clamp circuit 138 (FIG. 1) coupled between the input voltage terminal 106 and the first supply voltage terminal, HS.

According to certain examples, the HBM clamp circuit 136 in combination with the protection circuitry 302 operate to protect the first transistor 306 and the low-voltage circuitry 304 against voltage spikes that may be caused by ESD events. Although not illustrated in FIG. 3, in some examples, the individual low-voltage circuitry portions 304a-c may each include a low-voltage clamp (e.g., a 5V clamp circuit) in addition to the high-voltage overall HBM clamp circuit 136. The HBM clamp circuit 136 can be configured to trigger at a voltage level, Vtrigger, that is higher than the normal operating voltage (e.g., 200V) of the driver circuit 110. When an ESD event occurs, the HBM clamp circuit clamps the voltage between the second supply voltage terminal, HB, and the ground terminal 108 to a certain voltage level, Vclamp, and quickly discharges the second supply voltage terminal, HB, for example, through a capacitor included in the HBM clamp circuit 136. If the low-voltage circuitry portions 304a and 304c are protected by low-voltage clamps, as described above, then without the protection circuitry 302, the entire clamp voltage, Vclamp, would appear across the first transistor 306. As described above, in this instance, for the first transistor 306 to survive the ESD strike, the clamp voltage, Vclamp, would have to be set to lower than the breakdown voltage, Vb, of the first transistor.

To address this issue, the protection circuitry 302 includes a second transistor 308 that is coupled with the first transistor 306 in a cascode configuration. Accordingly, the second transistor 308 is referred to herein as the cascode transistor 308. The cascode transistor 308 may be implemented as an LDMOS transistor or another type of transistor. In the illustrated example, the first transistor 306 has a first terminal (e.g., a drain terminal) coupled via the third portion of the low-voltage circuitry 304c to the second supply voltage terminal, HB, and a second terminal (e.g., a source terminal) coupled to a first terminal (e.g., a drain terminal) of the cascode transistor 308. The cascode transistor 308 has a second terminal (e.g., a source terminal) coupled to the ground terminal 108. With this arrangement, in an ESD event, the clamp voltage, Vclamp, is shared across the stack created by the first transistor 306 in combination with the cascode transistor 308. The cascode transistor 308 can be selected having a breakdown voltage that adds a sufficient amount to the breakdown voltage of the first transistor 306 so as to exceed the clamp voltage, Vclamp. For example, to allow a 200V operating voltage for the circuit 300, the first transistor 306, implemented as a high-voltage LDMOS transistor, may have a breakdown voltage (e.g., Vds) of 260V, however, the HBM clamp circuit 136 may clamp at an even higher voltage, such as 305V, for example. Accordingly, in this example, to allow the stack of the first transistor 306 and the cascode transistor 308 to survive the ESD strike, the cascode device should be selected to have a breakdown voltage of at least 50V, for example, such that the combined breakdown voltage of the stack (260V+50V) exceeds the clamp voltage.

In addition, the control terminals (e.g., gates) of the first transistor 306 and the cascode transistor 308 are isolated using first and second switches 312, 314, respectively, to protect the devices and the circuitry coupled to the control terminals from damage during an ESD strike. In particular, the switches 312, 314 can be configured to, in an ESD event, effectively disconnect the control terminals of the first transistor 306 and the cascode transistor 308, respectively, from the signal source(s) and/or circuitry that may be coupled thereto. In particular, the first switch 312 may be a high-voltage switch that isolates the control terminal (e.g., gate) of the first transistor 306 from the low-voltage circuitry portion 304b. The second switch 314 isolates the Vcc terminal 124b from the control terminal (e.g., gate) of the cascode transistor 308.

In the example of FIG. 3, it is desirable that the control terminal of the first transistor 306 floats high during an ESD event. Accordingly, this outcome can be supported by configuring the first switch 312 to turn off in an ESD event. For example, the first switch 312 can be implemented using a drain-extended P-channel MOS transistor (DEPMOS transistor) having a first terminal coupled to the low-voltage circuitry 304b and a second terminal coupled to the gate of the first transistor 306. A control terminal of the first switch 312 is coupled to the second terminal of the first transistor 306 and the first terminal of the cascode transistor 308 (which position may also be identified as a junction terminal between the first transistor 306 and the cascode transistor 308), as shown in FIG. 3. With the illustrated arrangement, when the control terminal (gate) of the first switch 312 goes high (which occurs in an ESD strike on the second supply voltage terminal, HB, and the clamp voltage, Vclamp, is present across the stack of the first transistor 306 and the cascode transistor 308), the first switch 312 is turned off, thereby effectively disconnecting the control terminal of the first transistor 306 from the low-voltage circuitry 304b. The first switch 312 may be a high-voltage switch, as drain-source voltage, Vds, during an ESD event may be as high as the breakdown voltage of the cascode transistor 308 (e.g., 50V in the above example).

According to certain examples, the gate-source voltage (Vgs) of the first transistor 306 and of the transistor implementing the first switch 312 may be a relatively low voltage, such as ˜5.5V maximum, for example. Accordingly, to protect the gate-source junction of the first transistor 306 and the switch 312 during an ESD event, a Zener protection diode 320 may be added across the gate-source junction of the first transistor 306 and the switch 312, as shown in FIG. 3. Accordingly, during an ESD strike, as the source of the first transistor 306 floats up, the gate-source junction voltages of the first transistor 306 and the switch 312 are protected by the Zener protection diode 320.

The second switch 314 can be configured to be normally on, and to turn off in an ESD event. In order for the source of the first transistor 306 to float during an ESD event, the cascode transistor 308 should be off during an ESD event. Accordingly, the second switch 314 may be a low-voltage (e.g., 5V) MOS (or other) transistor, since it should not have to handle high voltages. In some examples, the second switch 314 is implemented as a P-channel MOS transistor having a first terminal coupled to a Vcc terminal 124b, a second terminal coupled to the control terminal of the cascode transistor 308, and a control terminal coupled to the ground terminal 108. According to certain examples, the control terminal of the second switch 314 is biased with a filter to isolate it from an ESD strike on the Vcc terminal 124b. In the example illustrated in FIG. 3, this filter is implemented as a resistive-capacitive (RC) filter including a capacitor 316 and a resistor 318. The capacitor 316 is coupled between the control terminal of the cascode transistor 308 and the ground terminal 108. The resistor 318 is coupled in parallel with the capacitor 316 between the control terminal of the cascode transistor 308 and the ground terminal 108. Thus, this RC filter is coupled to the control terminal of the cascode transistor 308 and ensures that, during an ESD event, the voltage at the control terminal of the cascode transistor 308 does not rise above 1-VT (VT being the threshold voltage of the cascode transistor 308). By selecting the transistor of the switch 314 to have a similar threshold voltage (VT) as the cascode transistor 308, the switch 314 is also turned off during an ESD event, assuming the voltage at the control terminal of the cascode transistor 308 does indeed remain below 1-VT.

The low-voltage circuitry portions 304a, 304c, coupled to the first transistor 306, are in a floating voltage domain (HB-HS), as described above. Thus, in an ESD event, the first transistor 306 is placed in a floating state, with its control terminal disconnected, its first terminal (e.g., drain) connected to the low-voltage circuitry 304a, 304c that is in a floating domain, and its second terminal also floating (connected to the cascode transistor 308 that is turned off, as described above). Additionally, as described above, the cascode transistor 308 is off, with its control terminal tied to ground. In this state, the first transistor 306 can withstand a voltage up to its breakdown voltage level, and the remainder of the clamp voltage is accommodated across the cascode device, which (provided that the cascode transistor 308 is appropriately selected) has a breakdown voltage sufficiently high to withstand this voltage.

In some examples, during an ESD event, the first transistor 306 first accommodates a drain-source voltage up to its breakdown voltage, after which the drain of the cascode transistor 308 begins to soak up the remaining/differential voltage (e.g., difference between the breakdown voltage of the first transistor 306 and the clamp voltage, Vclamp). As this happens, the voltage at gate of the switch 312 (implemented using a DEPMOS device in this example) rises. The Zener diode 320 connected between the gate and source terminals of the first transistor 306 ensures that the voltage at the gate of the first transistor 306 (which is also the voltage at the source of the switch 312) cannot fall below one diode-voltage less than the voltage at the gate of the switch 312 nor rise more than the Zener clamp voltage (e.g., ˜5V) above the gate voltage of the switch 312. For example, the gate of the switch 312 may go high first, while the source of the switch 312 is pulled up by the Zener diode 320 to within one diode voltage drop of the gate voltage. This ensures that the switch 312 (implemented as a DEPMOS) remains off and that its gate-source junction is protected by the Zener diode 320.

In another example, the switch 312 may be implemented using a high-voltage drain-extended N-channel MOS transistor (DENMOS transistor). In such an example, the gate of the DENMOS switch 312 may be tied to the gate of the cascode transistor 308 (which may also be implemented with a DENMOS device). In this configuration, during an ESD strike, the gate of the switch 312 remains off.

In some examples, during an ESD strike, the first transistor 306 may break down first when its breakdown voltage is reached, followed by the cascode transistor 308 soaking up the difference between the breakdown voltage of the first transistor 306 and the clamp voltage, as described above. However, in other examples, the cascode transistor 308 may clamp at its own breakdown voltage, followed by the remaining voltage (difference between the clamp voltage, Vclamp of the HBM clamp circuit 136) appearing across the first transistor 306. In either scenario, the switch 312 remains off, thereby protecting the low-voltage circuitry 304b.

Thus, the circuit 300 is protected against damage during an ESD event.

FIG. 4 illustrates a circuit 400 that is a variation of the circuit 300 and which may be part of the driver circuit 110. In this example, the stack comprising the first transistor 306 and the cascode transistor 308 is the same as in FIG. 3. Further, operation of the first and second switches 312, 314 and the RC filter (capacitor 316 and resistor 318) remain the same as described above with reference to FIG. 3. However, FIG. 4 illustrates a variation in the configuration of the low-voltage circuitry 304. In particular, in the example of FIG. 4, a fourth portion of low-voltage circuitry 304d is coupled between the first transistor 306 and the cascode transistor 308. The low-voltage circuitry portion 304d is further coupled to a fifth low-voltage circuitry portion 304e that is coupled between a Vcc terminal 124c and the ground terminal 108. It will be appreciated that the Vcc terminals 124a, 124b, 124c may represent the same Vcc terminal 124 or one or more individual Vcc terminals that may be connected to the same Vcc source or to two or more individual Vcc sources (which may supply the same or different Vcc voltage levels).

In the example of FIG. 4, the output of the first transistor 306 (e.g., the second terminal of the first transistor 306) is coupled to a low-voltage domain represented by the low-voltage circuitry 304d and 304c. In an ESD event, the low-voltage circuitry portion 304d is in a floating voltage domain. However, the low-voltage circuitry 304e is in a true low-voltage domain, coupled between the Vcc terminal 124c and the ground terminal 108. Accordingly, in an ESD event, the second terminal of the first transistor 306 also needs to be isolated or protected from the low-voltage circuitry portion 304c to prevent damage to the low-voltage circuitry portion 304c. According to certain examples, this protection is provided by a resistor 402 in combination with a diode stack including first and second diodes 404, 406. The resistor 402 and the diodes 404, 406 may be part of the protection circuitry 140 of FIG. 1. The resistor 402 has a first resistor terminal coupled to the low voltage circuitry portion 304d that is coupled between the first transistor 306 and the cascode transistor 308, and a second resistor terminal that is coupled to the low voltage circuitry portion 304c. The diodes 404, 406 are connected in series and in the same orientation between the Vcc terminal 124c and the ground terminal 108, with the diode 406 being connected between the second resistor terminal of the resistor 402 and the ground terminal 108, and the diode 404 being connected between the second resistor terminal of the resistor 402 and the Vcc terminal 124c, as shown in FIG. 4. Thus, the second resistor terminal of the resistor 402 is coupled toa junction terminal between the diodes 404, 406. The diodes 404, 406 are connected to block current flow from the Vcc terminal 124c to the ground terminal 108.

The resistor 402 and the diodes 404, 406 act as a clamp circuit 408 that protects the low-voltage circuitry 304c in the event that the high voltage (e.g., the breakdown voltage level of the cascode transistor 308, which may be 50V or 100V, etc., in certain examples) appears at the second terminal of the first transistor 306. For example, when a voltage approximately equal to (or close to) the breakdown voltage of the cascode transistor 308 appears across the cascode transistor 308, this voltage also appears across the resistor 402. Accordingly, a current will flow through the resistor 402 and the diode 404 connected to the Vcc terminal 124c. In the example of FIG. 4, the diodes 404 and 406 are forward biased. Thus, a voltage drop (approximately equal to the voltage across the cascode transistor 308) occurs across the resistor 402, and the voltage level at the second resistor terminal of the resistor 402 (and therefore at the connection to the low-voltage circuitry portion 304c) can be set by the forward-bias voltage of the diodes 404, 406 (e.g., ˜0.7V). Thus, the high voltage at the second terminal of the first transistor 306 is dropped across the resistor 402 to a low voltage level that can be accepted by the low-voltage circuitry portion 304c, and the low-voltage circuitry portion 304e is protected. The resistor 402 may have a high resistance value to limit the current flow to the Vcc terminal 124c.

Thus, the protection circuitry 140 of FIG. 1 can be configured to allow the first transistor 306, in configurations of the circuit 300 of FIG. 3, the circuit 400 of FIG. 4, or variations thereof, to survive a clamp voltage set by the HBM clamp circuit 136 (or 138) that is higher than the breakdown voltage of the first transistor 306. As described above, by adding the cascode transistor 308 and selecting the cascode transistor 308 to have an appropriate breakdown voltage, the clamp voltage is shared across the stack that includes both the first transistor 306 and the cascode transistor 308. By isolating the control terminals of the first transistor 306 and the cascode transistor 308 (e.g., using the switches 312, 314 as described above), the devices can be placed in a floating voltage domain in which the high clamp voltage is safely accommodated without damaging circuitry in the low-voltage domain (e.g., the low-voltage circuitry 304b or other circuitry coupled to the Vcc terminal(s) 124a, 124b). Further, in examples in which the output of the first transistor 306 is coupled to circuitry in a low-voltage domain (e.g., as in the circuit 400 of FIG. 4), the clamp circuit 408 comprised of the resistor 402 and diodes 404, 406 can be used to protect the low-voltage circuitry 304e from high voltage exposure and potential damage, as described above.

It will be appreciated that the circuitry 132 and/or 134 may include multiple first transistors 306, any of which may be connected in the configurations shown in FIG. 3 or FIG. 4, or some variation thereof. Accordingly, the protection circuitry 302, and optionally the clamp circuit comprised of the resistor 402 and the diode 404, 406 can be provided (e.g., as part of the protection circuitry 140) for any or all of the first transistors 306 needing ESD protection. In some examples, individual protection circuitry 302 (optionally with the clamp circuit 408) can be provided for each first transistor 306 being protected. Alternatively, some or all components of an instantiation of the protection circuitry 302 (optionally including the clamp circuit 408) may be shared by two or more first transistors 306. Variations consistent with the examples and techniques described herein may be apparent, and are intended to be part of this disclosure.

### Further Examples

Example 1 is a circuit comprising: a first transistor having a first terminal coupled to a first supply voltage source; a second transistor coupled between a second terminal of the first transistor and a ground terminal; a voltage clamp circuit coupled between the first supply voltage source and the ground terminal; a first switch coupled between a control terminal of the first transistor and a second supply voltage source, the first switch having a control terminal coupled to the second terminal of the first transistor; a second switch coupled between a control terminal of the second transistor and the second supply voltage source, the second switch having a control terminal coupled to the ground terminal; and a filter coupled between the control terminal of the second transistor and the ground terminal.

Example 2 includes the circuit of Example 1, wherein each of the first and second transistors has a breakdown voltage rating, and the breakdown voltage rating of the first transistor is equal to, lower than, or higher than the breakdown voltage rating of the second transistor.

Example 3 includes the circuit of one of Example 1 or 2, wherein at least one of the first transistor or the second transistor is a laterally-diffused metal oxide semiconductor (LDMOS) transistor.

Example 4 includes the circuit of any one of Examples 1-3, wherein the filter is a resistive-capacitive filter and comprises: a resistor coupled between the control terminal of the second transistor and the ground terminal; and a capacitor coupled in parallel with the resistor.

Example 5 includes the circuit of any one of Examples 1-4, wherein the first and second switches are field-effect transistor (FET) devices, and wherein the first and second transistors are metal-oxide semiconductor field effect (MOSFET) transistors.

Example 6 includes the circuit of Example 5, wherein the first and second switches are drain-extended P-channel MOS devices.

Example 7 includes the circuit of any one of Examples 1-6, wherein a clamp voltage of the voltage clamp circuit is higher than a breakdown voltage of the first transistor.

Example 8 includes the circuit of any one of Examples 1-7, further comprising control circuitry coupled between the first supply voltage source and the first transistor, and/or control circuitry coupled between the second supply voltage source and the ground terminal.

Example 9 includes the circuit of any one of Examples 1-7, further comprising: first control circuitry coupled between the second terminal of the first transistor and a first terminal of the second transistor; second control circuitry coupled between the second supply voltage source and the ground terminal; a resistor coupled between the first control circuitry and the second control circuitry; a first diode coupled between the resistor and the second supply voltage source; and a second diode coupled between the resistor and the ground terminal, the second diode having a same orientation as the first diode.

Example 10 is a DC-DC converter comprising the circuit of any one of Examples 1-9.

Example 11 is a circuit comprising: at least one driver coupled between first and second supply voltage terminals; control circuitry coupled to the at least one driver, the control circuitry comprising at least one transistor; an electrostatic discharge (ESD) clamp circuit coupled between the first supply voltage terminal and a ground terminal, the ESD clamp circuit having a clamp voltage that is higher than a breakdown voltage of the transistor; and protection circuitry coupled to the transistor and configured to extend a voltage rating of the transistor in combination with the protection circuitry to at least the clamp voltage of the ESD clamp circuit.

Example 12 includes the circuit of Example 11, wherein the at least one transistor is a laterally-diffused metal oxide semiconductor (LDMOS) transistor.

Example 13 includes the circuit of Example 12, wherein the protection circuitry comprises: a metal-oxide semiconductor field-effect transistor (MOSFET) coupled with the LDMOS transistor in a cascode configuration between the first supply voltage terminal and the ground terminal; a first switch coupled between a control terminal of the LDMOS transistor and a low-voltage supply terminal, the first switch having a control terminal coupled to a junction terminal between the LDMOS transistor and the MOSFET; and a second switch coupled between a control terminal of the MOSFET and the low-voltage supply terminal, the second switch having a control terminal coupled to the ground terminal.

Example 14 includes the circuit of Example 13, wherein the first switch is a drain-extended p-channel field effect (DEPMOS) or a drain-extended n-channel field effect (DENMOS) transistor.

Example 15 includes the circuit of one of Examples 13 or 14, wherein the protection circuitry further comprises a resistive-capacitive filter coupled between the control terminal of the MOSFET and the ground terminal.

Example 16 includes the circuit of any one of Examples 13-15, wherein a breakdown voltage of the MOSFET is lower than the breakdown voltage of the LDMOS transistor.

Example 17 includes the circuit of any one of Examples 13-16, wherein the control circuitry further comprises low-voltage circuitry coupled to the low-voltage supply terminal.

Example 18 is a power converter including the circuit of any one of Examples 11-17.

Example 19 is a power converter comprising: a high-side switching element coupled between an input voltage terminal and a switching terminal; a low-side switching element coupled between the switching terminal and a ground terminal; and a half-bridge driver circuit. The half-bridge driver circuit comprises a first driver coupled between first and second floating supply voltage terminals and to a control terminal of the high-side switching element, a second driver coupled between a low-voltage supply source and the ground terminal and to a control terminal of the low-side switching element, and control circuitry coupled to at least one of the first driver or the second driver, the control circuitry comprising at least one laterally-diffused metal oxide semiconductor (LDMOS) transistor. The half bridge driver circuit further comprises an electrostatic discharge (ESD) clamp circuit coupled between the first floating supply voltage terminal and the ground terminal, the ESD clamp circuit having a clamp voltage that is higher than a breakdown voltage of the LDMOS transistor, and protection circuitry coupled to the LDMOS transistor and configured to extend a voltage rating of the LDMOS transistor in combination with the protection circuitry to above the clamp voltage of the ESD clamp circuit.

Example 20 includes the power converter of Example 19, wherein the control circuitry comprises one or more of: zero-crossing detection circuitry; voltage level-shifting circuitry; under-voltage lock-out circuitry; and/or digital control circuitry.

Example 21 includes the power converter of one of Examples 19 or 20, wherein the protection circuitry comprises: a metal-oxide semiconductor field-effect transistor (MOSFET) coupled with the LDMOS transistor in a cascode configuration between the first floating voltage supply terminal and the ground terminal; a first switch coupled between a control terminal of the LDMOS transistor and a low-voltage supply terminal, the first switch having a control terminal coupled to a junction terminal between the LDMOS transistor and the MOSFET; and a second switch coupled between a control terminal of the MOSFET and the low-voltage supply terminal, the second switch having a control terminal coupled to the ground terminal.

Example 22 includes the power converter of Example 21, wherein the first switch is a drain-extended p-channel field effect transistor.

Example 23 includes the power converter of one of Examples 21 or 22, wherein the protection circuitry further comprises a resistive-capacitive filter coupled between the control terminal of the MOSFET and the ground terminal.

Example 24 is a circuit comprising: a first metal-oxide semiconductor field effect transistor (MOSFET) having a first terminal coupled to a first supply voltage source; a second MOSFET coupled between a second terminal of the first MOSFET and a ground terminal in a cascode configuration; an electrostatic discharge (ESD) clamp circuit coupled between the first supply voltage source and the ground terminal; a first switch coupled between a control terminal of the first MOSFET and a second supply voltage source, the first switch having a first switch control terminal coupled to the second terminal of the first MOSFET; a second switch coupled between a control terminal of the second MOSFET and the second supply voltage source, the second switch having a second switch control terminal coupled to the ground terminal; and a filter coupled between the control terminal of the second MOSFET and the ground terminal.

Example 25 includes the circuit of Example 24, wherein a breakdown voltage rating of the first MOSFET is higher than a breakdown voltage rating of the second MOSFET.

Example 26 includes the circuit of one of Examples 24 or 25, wherein at least one of the first MOSFET or the second MOSFET is a laterally-diffused metal oxide semiconductor (LDMOS) transistor.

Example 27 includes the circuit of any one of Examples 24-26, wherein the filter is a resistive-capacitive filter and comprises: a resistor coupled between the control terminal of the second MOSFET and the ground terminal; and a capacitor coupled in parallel with the resistor.

Example 28 includes the circuit of any one of Examples 24-27, wherein a clamp voltage of the ESD clamp circuit is higher than a breakdown voltage of the first MOSFET.

Example 29 includes the circuit of any one of Examples 24-28, wherein the second supply voltage source is a low-voltage supply voltage source, the circuit further comprising: low-voltage circuitry coupled between (i) the first supply voltage source and the first MOSFET, and/or (ii) the second supply voltage source and the ground terminal.

Example 30 includes the circuit of any one of Examples 24-28, wherein the second supply voltage source is a low-voltage supply voltage source, the circuit further comprising: first low-voltage circuitry coupled between the second terminal of the first MOSFET and a first terminal of the second MOSFET; second low-voltage circuitry coupled between the second supply voltage source and the ground terminal; a resistor coupled between the first low-voltage circuitry and the second low-voltage circuitry; a first diode coupled between the resistor and the second supply voltage source; and a second diode coupled between the resistor and the ground terminal, the second diode having a same orientation as the first diode.

Example 31 is a DC-DC power converter comprising the circuit of any one of Examples 24-30.

Example 32 is a half-bridge driver circuit for a power converter, comprising: at least one driver coupled between first and second floating supply voltage terminals; control circuitry coupled to the at least one driver, the control circuitry comprising at least one laterally-diffused metal oxide semiconductor (LDMOS) transistor; an electrostatic discharge (ESD) clamp circuit coupled between the first floating supply voltage terminal and a ground terminal, the ESD clamp circuit having a clamp voltage that is higher than a breakdown voltage of the LDMOS transistor; and protection circuitry coupled to the LDMOS transistor and configured to extend a voltage rating of the LDMOS transistor in combination with the protection circuitry to at least the clamp voltage of the ESD clamp circuit.

Example 33 includes the half-bridge driver circuit of Example 32, wherein the protection circuitry comprises: a metal-oxide semiconductor field-effect transistor (MOSFET) coupled with the LDMOS transistor in a cascode configuration between the first floating voltage supply terminal and the ground terminal; a first switch coupled between a control terminal of the LDMOS transistor and a low-voltage supply terminal, the first switch having a first switch control terminal coupled to a junction terminal between the LDMOS transistor and the MOSFET; and a second switch coupled between a control terminal of the MOSFET and the low-voltage supply terminal, the second switch having a second switch control terminal coupled to the ground terminal.

Example 34 includes the half-bridge driver circuit of Example 33, wherein the protection circuitry further comprises a resistive-capacitive filter coupled between the control terminal of the MOSFET and the ground terminal.

Example 35 includes the half-bridge driver circuit of one of Examples 33 or 34, wherein a breakdown voltage of the MOSFET is lower than the breakdown voltage of the LDMOS transistor.

Example 36 include the half-bridge driver circuit of any one of Examples 32-35, wherein the control circuitry further comprises low-voltage circuitry coupled to the low-voltage supply terminal.

Example 37 includes the half-bridge driver circuit of any one of Examples 32-36, wherein the first and second switches are field-effect transistor (FET) devices.

Example 38 includes the half-bridge driver circuit of Example 37, wherein the first switch is a drain-extended p-channel field effect transistor.

Example 39 is a power converter comprising the half-bridge driver circuit of any one of Examples 32-38.

Example 40 is a half-bridge driver circuit for a DC-DC power converter, comprising: an LDMOS transistor, an HBM clamp circuit, and protection circuitry configured to enable the LDMOS transistor to withstand a clamp voltage set by the HBM clamp circuit that is higher than a breakdown voltage of the LDMOS transistor.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end user and/or a third party.

While the use of particular transistors is described herein, other transistors (or equivalent devices) may be used instead. For example, a p-channel field effect transistor (PFET) may be used in place of an n-channel field effect transistor (NFET) with little or no changes to the circuit. Furthermore, other types of transistors may be used (such as bipolar junction transistors (BJTs)). Furthermore, the devices may be implemented in/over a silicon substrate (Si), a silicon carbide substrate (SiC), a gallium nitride substrate (GaN) or a gallium arsenide substrate (GaAs). Moreover, reference to transistor features such as gate, source, or drain is not intended to exclude any suitable transistor technologies. For instance, features such as source, drain, and gate are typically used to refer to a FET, while emitter, collector, and base are typically used to refer to a BJT. Such features may be used interchangeably herein. For instance, reference to the gate of a transistor may refer to either the gate of a FET or the base of a BJT, and vice-versa. In some examples, a control terminal may refer to either the gate of a FET or the base of a BJT. Any other suitable transistor technologies can be used. Any such transistors can be used as a switch, with the gate or base or other comparable feature acting as a switch select input that can be driven to connect the source and drain (or the emitter and collector, as the case may be).

References herein to a field effect transistor (FET) being “ON” (or a switch being closed) means that the conduction channel of the FET is present, and drain current may flow through the FET. References herein to a FET being “OFF” (or a switch being open) means that the conduction channel is not present, and drain current does not flow through the FET. A FET that is OFF, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within a range of that parameter, such as +/−10 percent of that parameter or +/−5 percent of that parameter.

Modifications are possible in the described examples, and other examples are possible within the scope of the claims.

What is claimed is:

1. A circuit comprising:
a first transistor having a first terminal coupled to a first supply voltage source;
a second transistor coupled between a second terminal of the first transistor and a ground terminal;
a voltage clamp circuit coupled between the first supply voltage source and the ground terminal;
a first switch coupled between a control terminal of the first transistor and a second supply voltage source, the first switch having a control terminal coupled to the second terminal of the first transistor;
a second switch coupled between a control terminal of the second transistor and the second supply voltage source, the second switch having a control terminal coupled to the ground terminal; and
a filter coupled between the control terminal of the second transistor and the ground terminal.

2. The circuit of claim 1, wherein each of the first and second transistors has a breakdown voltage rating, and the breakdown voltage rating of the first transistor is higher than the breakdown voltage rating of the second transistor.

3. The circuit of claim 1, wherein each of the first and second transistors has a breakdown voltage rating, and the breakdown voltage rating of the first transistor is equal to or lower than the breakdown voltage rating of the second transistor.

4. The circuit of claim 1, wherein at least one of the first transistor or the second transistor is a laterally-diffused metal oxide semiconductor (LDMOS) transistor.

5. The circuit of claim 1, wherein the filter is a resistive-capacitive filter and comprises:
a resistor coupled between the control terminal of the second transistor and the ground terminal; and
a capacitor coupled in parallel with the resistor.

6. The circuit of claim 1, wherein a clamp voltage of the voltage clamp circuit is higher than a breakdown voltage of the first transistor.

7. The circuit of claim 1, further comprising:
control circuitry coupled between the first supply voltage source and the first transistor; and/or
control circuitry coupled between the second supply voltage source and the ground terminal.

8. The circuit of claim 1, further comprising:
first control circuitry coupled between the second terminal of the first transistor and a first terminal of the second transistor;
second control circuitry coupled between the second supply voltage source and the ground terminal;
a resistor coupled between the first control circuitry and the second control circuitry;
a first diode coupled between the resistor and the second supply voltage source; and
a second diode coupled between the resistor and the ground terminal, the second diode having a same orientation as the first diode.

9. A circuit comprising:
at least one driver coupled between first and second supply voltage terminals;
control circuitry coupled to the at least one driver, the control circuitry comprising at least one transistor;
an electrostatic discharge (ESD) clamp circuit coupled between the first supply voltage terminal and a ground terminal, the ESD clamp circuit having a clamp voltage that is higher than a breakdown voltage of the transistor; and
protection circuitry coupled to the transistor and configured to extend a voltage rating of the transistor in combination with the protection circuitry to at least the clamp voltage of the ESD clamp circuit.

10. The circuit of claim 9, wherein the at least one transistor is a laterally-diffused metal oxide semiconductor (LDMOS) transistor.

11. The circuit of claim 10, wherein the protection circuitry comprises:
a metal-oxide semiconductor field-effect transistor (MOSFET) coupled with the LDMOS transistor in a cascode configuration between the first supply voltage terminal and the ground terminal;
a first switch coupled between a control terminal of the LDMOS transistor and a low-voltage supply terminal, the first switch having a control terminal coupled to a junction terminal between the LDMOS transistor and the MOSFET; and
a second switch coupled between a control terminal of the MOSFET and the low-voltage supply terminal, the second switch having a control terminal coupled to the ground terminal.

12. The circuit of claim 11, wherein the protection circuitry further comprises:
a resistive-capacitive filter coupled between the control terminal of the MOSFET and the ground terminal.

13. The circuit of claim 11, wherein a breakdown voltage of the MOSFET is lower than the breakdown voltage of the LDMOS transistor.

14. The circuit of claim 11, wherein the control circuitry further comprises low-voltage circuitry coupled to the low-voltage supply terminal.

15. The circuit of claim 11, wherein the first switch is a drain-extended p-channel field effect transistor.

16. A power converter comprising:
a high-side switching element coupled between an input voltage terminal and a switching terminal;
a low-side switching element coupled between the switching terminal and a ground terminal; and
a half-bridge driver circuit comprising:
a first driver coupled between first and second floating supply voltage terminals and to a control terminal of the high-side switching element,
a second driver coupled between a low-voltage supply source and the ground terminal and to a control terminal of the low-side switching element,
control circuitry coupled to at least one of the first driver or the second driver, the control circuitry comprising at least one laterally-diffused metal oxide semiconductor (LDMOS) transistor,
an electrostatic discharge (ESD) clamp circuit coupled between the first floating supply voltage terminal and the ground terminal, the ESD clamp circuit having a clamp voltage that is higher than a breakdown voltage of the LDMOS transistor, and
protection circuitry coupled to the LDMOS transistor and configured to extend a voltage rating of the LDMOS transistor in combination with the protection circuitry to above the clamp voltage of the ESD clamp circuit.

17. The power converter of claim 16, wherein the control circuitry comprises one or more of:
zero-crossing detection circuitry;
voltage level-shifting circuitry;
under-voltage lock-out circuitry; and/or
digital control circuitry.

18. The power converter of claim 16, wherein the protection circuitry comprises:
a metal-oxide semiconductor field-effect transistor (MOSFET) coupled with the LDMOS transistor in a cascode configuration between the first floating voltage supply terminal and the ground terminal;
a first switch coupled between a control terminal of the LDMOS transistor and a low-voltage supply terminal, the first switch having a control terminal coupled to a junction terminal between the LDMOS transistor and the MOSFET; and
a second switch coupled between a control terminal of the MOSFET and the low-voltage supply terminal, the second switch having a control terminal coupled to the ground terminal.

19. The power converter of claim 18, wherein the first switch is a drain-extended p-channel field effect transistor.

20. The power converter of claim 18, wherein the protection circuitry further comprises:
a resistive-capacitive filter coupled between the control terminal of the MOSFET and the ground terminal.
